(19) United States
(12) Patent Application Publication
(10) Pub. No.: US 2026/0147964 A1
(43) Pub. Date: May 28, 2026

(54) Regional seismic liquefaction space-time field construction method fusing physical simulation and machine learning

(71) Applicant: Tianjin University, Tianjin (CN)

(72) Inventors: Zhenning BA, Tianjin (CN); Shujuan HAN, Tianjin (CN); Yan LU, Tianjin (CN); Mengtao WU, Tianjin (CN)

(73) Assignee: Tianjin University, Tianjin (CN)

(21) Appl. No.: 19/399,903

(22) Filed: Nov. 25, 2025

(30) Foreign Application Priority Data
Nov. 25, 2024 (CN) 2024116968779

(51) Int. Cl. G06F 30/27

(52) U.S. Cl. CPC G06F 30/27

(57) ABSTRACT

The present invention discloses a regional seismic liquefaction spatio-temporal field construction method fusing physical simulation and machine learning, and the method comprises the following steps: selecting an evaluation region, and dividing the region through a kilometer grid; constructing a ground motion spatio-temporal field of the evaluation region to obtain ground motion data of each of grid points; collecting seismic liquefaction site data to construct a training set; performing seismic liquefaction grade evaluation training by the training set to generate a seismic liquefaction grade model; performing liquefaction grade evaluation on each of the grid points of the evaluation region to obtain liquefaction grade evaluation results; and drawing a stratigraphic liquefaction grade spatial distribution map of the evaluation region based on site soil liquefaction grade evaluation results.

### CROSS-REFERENCE

This application claims the benefit of priority from China Patent Application No. CN 2024116968779 filed on Nov. 25 2024, the contents of which are hereby incorporated by reference in their entirety.

### TECHNICAL FIELD

The present invention relates to the technical field of geotechnical earthquake engineering, and in particular, to a regional seismic liquefaction spatio-temporal field construction method fusing physical simulation and machine learning.

### BACKGROUND ART

Over the past two decades, catastrophic earthquakes worldwide have frequently been accompanied by extensive liquefaction, leading to differential settlement of building foundations and severe damage to underground facilities. Given China's complex engineering geological conditions and potential seismic hazards, researching the spatial distribution of site seismic liquefaction grades and scientifically quantifying the liquefaction hazard degree of soil layers are crucial tasks for ensuring engineering seismic safety.

Numerous factors cause seismic liquefaction, and there exists a highly nonlinear relationship between the ground motion and soil parameters affecting liquefaction and the conclusions of site seismic liquefaction grade evaluation. Machine learning methods are practical tools for learning from data based on probabilistic models, possessing both the ability to extract complex patterns and effective features from data streams and the potential to induce new characteristics and mechanisms, offering new perspectives for seismic liquefaction grade evaluation. Commonly used machine learning methods include Linear Regression, Logistic Regression, Naive Bayes algorithm, Support Vector Machine, Random Forest, and Artificial Neural Network, among others. Among them, the Artificial Neural Network (ANN) simulates the structure of a biological nervous system, exhibits strong nonlinear mapping capabilities, primarily relies on learning from past experiences in sample data without requiring predefined mathematical models, and is suitable for handling nonlinear problems such as site seismic liquefaction evaluation.

Ground motion is a critical factor affecting seismic liquefaction. The ground motion spatio-temporal field of an evaluation region can be calculated through physical simulation methods, providing ground motion parameters for evaluating the liquefaction grade of the site soil. Currently, physical simulation methods for ground motion can be broadly categorized into three types based on the underlying theory:
deterministic methods, stochastic methods, and hybrid methods. Deterministic methods typically use the constitutive relation of the medium and Newton's second law as the foundation, solve the wave equation for seismic wave propagation, and achieve numerical simulation through numerical solution techniques such as the Finite Difference Method, Finite Element Method, and Spectral Element Method. The Spectral Element Method (SEM) is a numerical method capable of simulating three-dimensional wave fields in large-scale complex geological structures. Based on this method, Komatitsch et al. developed the SPECFEM3D software package, which can simulate seismic wave fields excited by sources in acoustic, elastic, and viscoelastic media.

Evaluating the liquefaction grade only at individual sampling points makes it difficult to reflect the spatial distribution information of site seismic liquefaction, thereby hindering rapid and effective assessment of the seismic liquefaction situation across the entire site. Geographic Information System (GIS) is a discipline that involves the acquisition, storage, manipulation, management, modeling, and display of geographic data (spatial location, attribute characteristics, temporal characteristics) in space, supported by computer hardware and software. It not only possesses strong spatial analysis capabilities but also enables the visualization of spatial data, making it suitable for displaying the spatial distribution of site seismic liquefaction grades.

In summary, site liquefaction during earthquakes is characterized by high randomness and uncertainty, influenced by multiple factors, and exhibiting a highly nonlinear relationship between these factors and the seismic liquefaction grade evaluation conclusions. Furthermore, evaluating the liquefaction grade only at individual sampling points cannot reflect the seismic liquefaction situation of the entire site. Given the above, how to accurately evaluate the liquefaction grade of site liquefaction during earthquakes and intuitively and clearly display the spatial distribution of site seismic liquefaction grades is a problem urgently needing resolution.

### SUMMARY OF THE INVENTION

The objective of the present invention is to provide a regional seismic liquefaction spatio-temporal field construction method fusing physical simulation and machine learning, which can perform seismic liquefaction grade evaluation of the site soil under a scenario earthquake, and can reflect the spatial variation of the site seismic liquefaction grade while assessing the liquefaction hazard degree of the soil layer.

To achieve the above objective, the present invention provides a regional seismic liquefaction spatio-temporal field construction method fusing physical simulation and machine learning, comprising the following steps:
S1. Selecting an evaluation region, and dividing the evaluation region through a kilometer grid;
S2. Constructing a ground motion spatio-temporal field for the evaluation region through a physical simulation method, to obtain ground motion data of each of grid points;
S3. Collecting seismic liquefaction site data to construct a training set, wherein the seismic liquefaction site data comprises liquefaction grade evaluation factors;
S4. Performing seismic liquefaction grade training through a machine learning method, establishing a nonlinear relationship between the liquefaction grade evaluation factors and site seismic liquefaction grade evaluation conclusions in the training set, and generating a seismic liquefaction grade evaluation model;
S5. Performing liquefaction grade evaluation on each of the grid points of the evaluation region according to the seismic liquefaction grade model, and obtaining liquefaction grade evaluation results;
S6. Spatially compositing site soil liquefaction grade evaluation results through GIS technology, and generating a stratigraphic liquefaction grade spatial distribution map of the evaluation region.

Preferably, S1 specifically comprises:
S1.1. Selecting the evaluation region and determining a scope of the evaluation region;
S1.2. Dividing the evaluation region into a plurality of 1 km×1 km grids according to a unified standard through the kilometer grid;
S1.3. Taking soil layer parameters at centers of each of the grids as geological data within a grid range, thereby providing geological parameters for evaluating a liquefaction grade of the site soil.

Preferably, S2 specifically comprises:
S2.1. Selecting source parameters of a scenario earthquake for the evaluation region, the source parameters comprising global source parameters and local source parameters, wherein the global source parameters comprise position and dimensions of a fault, magnitude, focal mechanism, source depth, and average slip on a fault plane, and the local source parameters comprise position and dimensions of a asperity, and slip of the asperity;
S2.2. Constructing an integrated physical model comprising a finite-fault source, crustal velocity structure, and complex site conditions, and calculating a ground motion spatio-temporal field of the evaluation region through a physical simulation method based on the integrated physical model;
S2.3. Obtaining ground motion data for each of grid points in the evaluation region based on the ground motion spatio-temporal field, thereby providing ground motion parameters for evaluating the liquefaction grade of the site soil.

Preferably, the physical simulation method utilized in S2.2 comprises deterministic Spectral Element Method, Finite Difference Method, stochastic methods, and hybrid methods.

Preferably, the machine learning method in S4 comprises Linear Regression, Logistic Regression, Naive Bayes algorithm, Support Vector Machine algorithm, Random Forest algorithm, and Artificial Neural Network algorithm, and the like.

Preferably, in S4, a Backpropagation (BP) neural network based on the Levenberg-Marquardt algorithm is adopted for seismic liquefaction grade evaluation training to generate the seismic liquefaction grade evaluation model, wherein the seismic liquefaction grade evaluation model comprises a 3-layer neural network, namely an input layer, a hidden layer, and an output layer, and the number of neurons in the input layer is 6, and the number of neurons in the hidden layer is 10, with specific steps as follows:
S4.1. Forward propagation of information, configuring the 6 liquefaction grade evaluation factors from the training set as the neurons of the input layer, processing and nonlinearly transforming them through the hidden layer, and then transmitting them to the output layer;
S4.2. Backward propagation of error layer by layer, after the information reaches the output layer, utilizing a loss function to calculate prediction error, then propagating error terms from the output layer back to the hidden layer, and finally to the input layer;
S4.3. Iterative updating of weights and thresholds, calculating the error in each iteration, updating weight and threshold parameters by calculating gradient of the loss function with respect to output results, repeating the forward propagation of information process described above after obtaining the updated weight and threshold parameters, until the error is less than a certain value to terminate the iteration, determining final weight and threshold results, completing model training, and generating the seismic liquefaction grade evaluation model.

Preferably, S5 specifically comprises: configuring the peak acceleration of the ground motion and duration of the ground motion obtained from ground motion spatio-temporal field simulation under scenario earthquake, and relative density, groundwater level, soil layer depth, and thickness of overlying non-liquefiable soil layer at each of the grid points in a evaluation region as input parameters for BP neural network, and performing liquefaction grade evaluation on each of the grid points according to a seismic liquefaction grade model, and obtaining liquefaction grade evaluation results.

Preferably, S6 specifically comprises:
S6.1. Configuring quantified values of three-dimensional site soil liquefaction grade evaluation results as input data sources for GIS software;
S6.2. Performing interpolation calculation on the quantified values of the liquefaction grade evaluation results by spatial interpolation algorithm of the GIS;
S6.3. Performing three-dimensional volume imaging of the liquefaction grade by generated three-dimensional data, and drawing a stratigraphic liquefaction grade spatial distribution map of the evaluation region.

Therefore, the present invention employs the aforementioned steps of the regional seismic liquefaction spatio-temporal field construction method fusing physical simulation and machine learning, which achieves seismic liquefaction grade evaluation of the site soil under a scenario earthquake based on physical simulation and machine learning. By combining spatial three-dimensional interpolation and volume visualization techniques, it establishes corresponding three-dimensional stratigraphic models from discrete site liquefaction grade data, intuitively displaying the liquefaction grade evaluation results graphically. Compared to traditional seismic liquefaction potential evaluation, it possesses the significant advantages of intuitively reflecting the spatial variation of site seismic liquefaction grades and the liquefaction hazard degree of the site soil layers.

Hereinafter, the technical solutions of the present invention is further described in detail through the accompanying drawings and embodiments.

### DESCRIPTION OF DRAWINGS

In order to explain the embodiments of the present invention or the technical solutions in the prior art more clearly, the following briefly introduces the accompanying drawings required for describing the embodiments. Obviously, the accompanying drawings in the following description show only some embodiments of the present invention, and those of ordinary skill in the art can obtain other drawings based on these drawings without creative efforts.

FIG. 1 is a flowchart of the regional seismic liquefaction spatio-temporal field construction method fusing physical simulation and machine learning;

FIG. 2 is a schematic diagram of dividing the evaluation region through a kilometer grid;

FIG. 3 is a schematic structural diagram of a seismic liquefaction grade evaluation model;

FIG. 4 is a flowchart for three-dimensional visualization modeling of the seismic liquefaction grade in an evaluation region;

FIG. 5 is a stratigraphic liquefaction grade spatial distribution map of the evaluation region; and

FIG. 6 is a schematic diagram of a two-dimensional profile of the stratigraphic liquefaction grade in the evaluation region.

### EMBODIMENTS

Hereinafter, the technical solutions in the embodiments of the present invention will be described clearly and completely with reference to the accompanying drawings in the embodiments of the present invention. Obviously, the described embodiments are only a part of the embodiments of the present invention, rather than all of them. All other embodiments obtained by those of ordinary skill in the art based on the embodiments of the present invention without creative efforts shall fall within the protection scope of the present invention.

To make the aforementioned objectives, features, and advantages of the present invention more comprehensible, a detailed description is provided below in conjunction with the accompanying drawings and specific embodiments.

### Embodiments

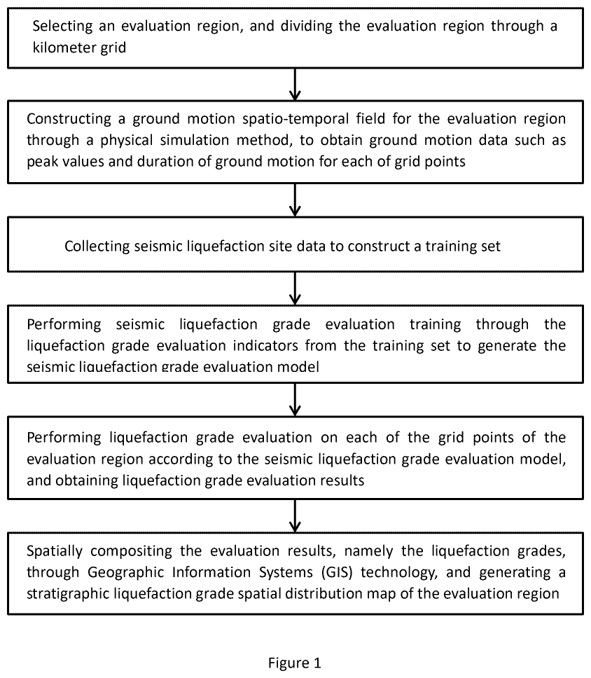

An embodiment of the present invention provides a regional seismic liquefaction spatio-temporal field construction method fusing physical simulation and machine learning. As shown in FIG. 1, the method comprises the following steps:
S1. Selecting an evaluation region, and dividing the evaluation region through a kilometer grid;
S2. Constructing a ground motion spatio-temporal field for the evaluation region through a physical simulation method, to obtain ground motion data such as peak values and duration of ground motion of each of grid points;
S3. Collecting seismic liquefaction site data to construct a training set, wherein the seismic liquefaction site data comprises liquefaction grade evaluation factors;
S4. Performing seismic liquefaction grade training through a Backpropagation (BP) neural network based on the Levenberg-Marquardt algorithm, establishing a nonlinear relationship between factors such as ground motion and soil parameters affecting liquefaction in the training set and site seismic liquefaction grade evaluation conclusions, and generating a seismic liquefaction grade evaluation model;
S5. Performing liquefaction grade evaluation on each of the grid points of the evaluation region according to the seismic liquefaction grade model, and obtaining liquefaction grade evaluation results; and
S6, Spatially compositing site soil liquefaction grade evaluation results through GIS technology, and generating a stratigraphic liquefaction grade spatial distribution map of the evaluation region.

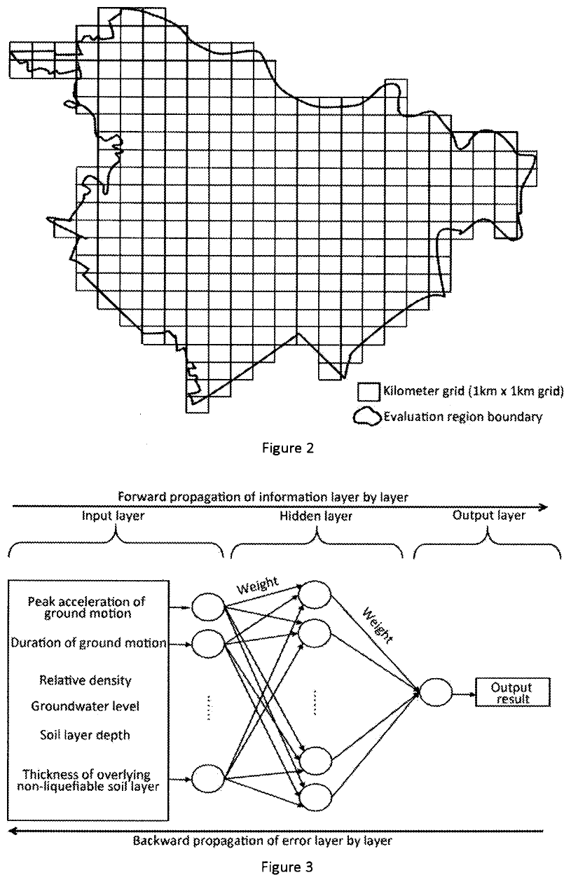

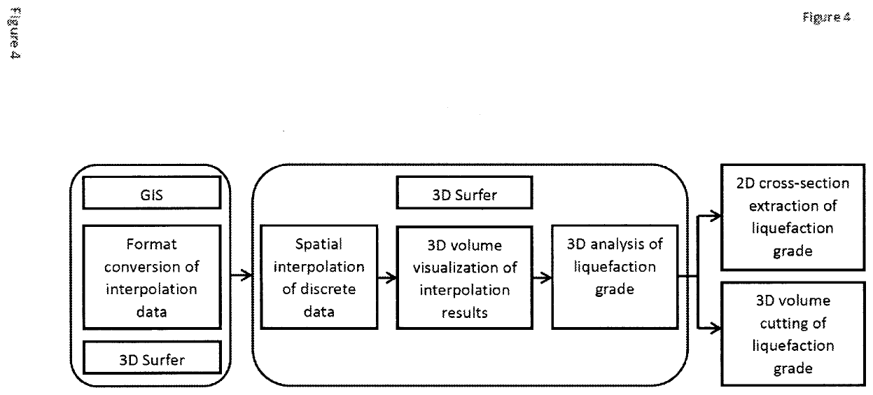

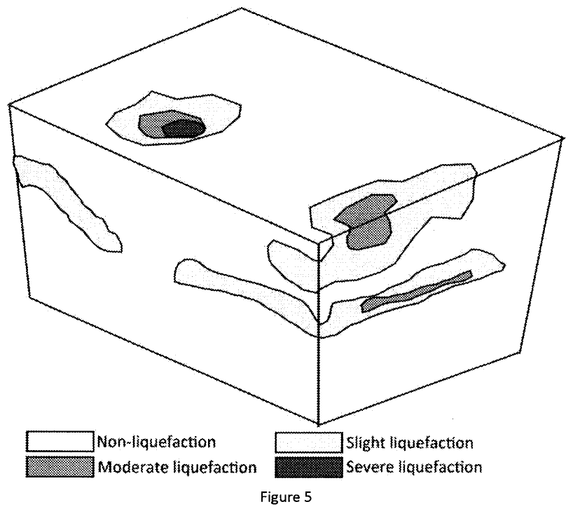

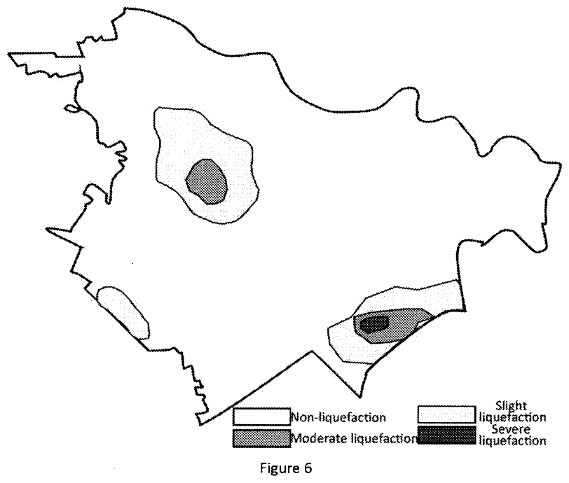

Hereinafter, the implementation of the present invention is further described with reference to FIGS. 2 to 6.
S1. Selecting an evaluation region, and dividing the evaluation region through a kilometer grid, as shown in FIG. 2, the specific method is as follows:
Selecting the evaluation region and determining a scope of the evaluation region; Dividing the evaluation region into a plurality of 1 km×1 km grids according to a unified standard through the kilometer grid; Taking soil layer parameters at centers of each of the grids as geological data within a grid range, thereby providing geological parameters for evaluating a liquefaction grade of the site soil.
S2. Constructing a ground motion spatio-temporal field for the evaluation region through a physical simulation method, to obtain ground motion data such as peak values and duration of ground motion of each of grid points, the specific method is as follows:
S2.1. Selecting source parameters of a scenario earthquake for the evaluation region; constructing an integrated physical model comprising a finite-fault source, crustal velocity structure, and complex site conditions, wherein the finite-fault source adopts the GP14.3 hybrid source model, setting global source parameters such as the position and dimensions of the fault, magnitude, focal mechanism, source depth, and average slip on the fault plane, and local source parameters such as the position and dimensions of an asperity and the slip of the asperity in the model, and generating a source spatio-temporal distribution file based on the SPECFEM3D format;
S2.2. Importing the aforementioned source spatio-temporal distribution file into SPECFEM3D, and calculating the ground motion spatio-temporal field of the evaluation region;
S2.3. Obtaining ground motion data such as peak values and duration of ground motion for each grid point in the evaluation region based on the aforementioned ground motion spatio-temporal field, storing them in tabular form, thereby providing ground motion parameters for evaluating the liquefaction grade of the site soil.
S3. Collecting seismic liquefaction site data to construct a training set, wherein the seismic liquefaction site data comprises liquefaction grade evaluation factors, the specific method is as follows:
Collecting seismic liquefaction site data. The original data utilized in the present embodiment includes measured data from multiple earthquakes worldwide, particularly several major earthquakes in recent years, and introduces measured data of site liquefaction characteristics from several major earthquakes in China, including the Tonghai, Haicheng, and Tangshan earthquakes, totaling 297 sets of measured site liquefaction data, including 184 liquefied sites and 113 non-liquefied sites, and using the collected seismic liquefaction site data as the training set. Based on the aforementioned data, 6 liquefaction grade evaluation factors are considered, namely, peak acceleration of ground motion, duration of ground motion, relative density, groundwater level, soil layer depth, and thickness of the overlying non-liquefiable soil layer.
S4. Performing seismic liquefaction grade training, and generating a seismic liquefaction grade evaluation model:
A Backpropagation (BP) neural network is a multi-layer feedforward network trained by error back propagation and belongs to one type of artificial neural network. The BP neural network is used to perform seismic liquefaction grade evaluation training using the Levenberg-Marquardt algorithm on the liquefaction grade evaluation factors in the training set. The structure of the generated seismic liquefaction grade evaluation model is shown in FIG. 3, the specific method is as follows:
S4.1. Forward propagation of information: namely, configuring the 6 liquefaction grade evaluation factors from the training set as the neurons of the input layer, transmitting the data from the input layer to the output layer after processing and nonlinear transformation through the hidden layer. The number of layers for the input layer, output layer, and hidden layer is 1, the number of neurons in the hidden layer is 10, and the output layer outputs the category of the test data, divided into four classes: non-liquefaction, slight liquefaction, moderate liquefaction, and severe liquefaction. The activation function for both the hidden layer neurons and the output layer is selected as the Sigmoid function (S-shaped function). During the forward propagation from the input layer to the hidden layer, the sample parameters of the liquefaction grade evaluation factors are transmitted from the input layer through the hidden layer's layer-by-layer processing and nonlinear transformation to the output layer;
S4.2. Backward propagation of error layer by layer: namely, after the information reaches the output layer, utilizing a loss function to calculate the prediction error, then propagating the error terms from the output layer back to the hidden layer, and finally to the input layer;
S4.3. Iterative updating of weights and thresholds during the process: namely, apportioning the error to each layer during propagation and then updating the weights of the neurons in each layer, adjusting the connection strengths and thresholds between the hidden layer and the input layer, and between the hidden layer and the output layer to reduce the error along the gradient direction. After obtaining the updated weight and threshold parameters, the forward propagation of information process described above is repeated. During a large number of repeated learning and training processes, the evaluation accuracy of the model is correspondingly improved. When the error is less than a certain value, the iteration is terminated, the final weight and threshold results are determined, the model training is completed, and the seismic liquefaction grade evaluation model is generated. Through the transformation of the initial input data representation by the neurons in the hidden layer of the neural network, the neurons in the final layer can complete the evaluation of the liquefaction grade. The seismic liquefaction grade evaluation method proposed in the present application can comprehensively reflect the nonlinear relationship between various influencing factors and the site liquefaction grade, possesses high data recognition capability and liquefaction grade evaluation accuracy, and the model can serve as a novel multi-parameter comprehensive evaluation model to correctly predict the seismic site liquefaction grade.
S5. Performing liquefaction grade evaluation on each of the grid points of the evaluation region according to the seismic liquefaction grade model, and obtaining liquefaction grade evaluation results, the specific method is as follows:
Configuring the peak acceleration of the ground motion, duration of the ground motion, relative density, groundwater level, soil layer depth, and thickness of the overlying non-liquefiable soil layer at each of the grid points in the evaluation region obtained from the ground motion spatio-temporal field simulation under the scenario earthquake as input parameters for the BP neural network, and performing liquefaction grade evaluation on each grid point according to the seismic liquefaction grade model, and obtaining liquefaction grade evaluation results.
S6, Spatially compositing site soil liquefaction grade evaluation results through GIS technology, and generating a stratigraphic liquefaction grade spatial distribution map of the evaluation region, as shown in FIG. 4, the specific method is as follows:
S6.1. Based on the concept of a Digital Elevation Model (DEM), equating the quantified values of the site seismic liquefaction grade evaluation results to the elevation data in the DEM model, converting the three-dimensional information of the site liquefaction grade from the GIS into a data format supported by the visualization software—3D Surfer (a 3D mapping software developed by Golden Software, USA), to achieve the conversion of the interpolation data format;
S6.2. Invoking 3D Surfer, based on the Kriging interpolation principle, performing interpolation calculation on the quantified values of the three-dimensional site soil liquefaction grade evaluation results through a variogram, thereby estimating the soil layer liquefaction grade at unpredicted points using the information (liquefaction grade) of known prediction points;
S6.3. Based on three-dimensional volume visualization technology, utilizing the three-dimensional data generated by the aforementioned interpolation, assigning different color values and opacity values according to the different attributes of the voxels, and generating a three-dimensional model of the site liquefaction grade, as shown in FIG. 5; based on the three-dimensional volume imaging of the liquefaction grade, utilizing the volume cutting and slice creation functions to realize the creation of three-dimensional cutaways and two-dimensional profiles (as shown in FIG. 6) of the site liquefaction grade, thereby enabling three-dimensional analysis of the site liquefaction grade. By combining spatial three-dimensional interpolation and volume visualization techniques, corresponding three-dimensional stratigraphic models can be established based on discrete site liquefaction grade data, and the site liquefaction grade evaluation results can be displayed intuitively in graphical form, effectively reflecting the spatial variation of the site seismic liquefaction grade and the liquefaction hazard degree of the site soil layers.

For the remaining technical features in the aforementioned embodiments, those skilled in the art can flexibly select them according to actual conditions to meet different specific practical needs. However, it is obvious to those of ordinary skill in the art that these specific details are not necessary to implement the present invention. In other instances, well-known components, structures, or parts have not been described in detail to avoid obscuring the present invention, and all fall within the technical protection scope defined by the claims of the present invention.

Modifications and variations made by those skilled in the art without departing from the spirit and scope of the present invention shall fall within the protection scope of the appended claims of the present invention. In the above description, numerous specific details are set forth to provide a thorough understanding of the present invention. However, it is obvious to those of ordinary skill in the art that these specific details are not necessary to implement the present invention. In other instances, well-known techniques, such as specific construction details, operating conditions, and other technical conditions, have not been described in detail to avoid confusing the present invention.

Specific examples are used in the document to illustrate the principles and implementation of the present invention. The description of the above embodiments is only used to help understand the method and core ideas of the present invention. Meanwhile, for those of ordinary skill in the art, based on the ideas of the present invention, there will be changes in the specific implementation and application scope. In summary, the content of the present specification should not be construed as limiting the present invention.

1. A regional seismic liquefaction spatio-temporal field construction method fusing physical simulation and machine learning, comprising the following steps:
S1, selecting an evaluation region, and dividing the evaluation region through a kilometer grid;
S2, constructing a ground motion spatio-temporal field for the evaluation region through a physical simulation method, to obtain ground motion data of each of grid points;
S3, collecting seismic liquefaction site data to construct a training set, wherein the seismic liquefaction site data comprises liquefaction grade evaluation factors;
S4, performing seismic liquefaction grade training through a machine learning method, establishing a nonlinear relationship between the liquefaction grade evaluation factors and site seismic liquefaction grade evaluation conclusions in the training set, and generating a seismic liquefaction grade evaluation model;
S5, performing liquefaction grade evaluation on each of the grid points of the evaluation region according to the seismic liquefaction grade model, and obtaining liquefaction grade evaluation results; and
S6, spatially compositing site soil liquefaction grade evaluation results through GIS technology, and generating a stratigraphic liquefaction grade spatial distribution map of the evaluation region.

2. The regional seismic liquefaction spatio-temporal field construction method fusing physical simulation and machine learning according to claim 1, wherein S1 specifically comprises:
S1.1, selecting the evaluation region and determining a scope of the evaluation region;
S1.2, dividing the evaluation region into a plurality of 1 km×1 km grids according to a unified standard through the kilometer grid; and
S1.3, taking soil layer parameters at centers of each of the grids as geological data within a grid range, thereby providing geological parameters for evaluating a liquefaction grade of the site soil.

3. The regional seismic liquefaction spatio-temporal field construction method fusing physical simulation and machine learning according to claim 2, wherein S2 specifically comprises:
S2.1, selecting source parameters of a scenario earthquake for the evaluation region, the source parameters comprising global source parameters and local source parameters, wherein the global source parameters comprise position and dimensions of a fault, magnitude, focal mechanism, source depth, and average slip on a fault plane, and the local source parameters comprise position and dimensions of a asperity, and slip of the asperity;
S2.2, constructing an integrated physical model comprising a finite-fault source, crustal velocity structure, and complex site conditions, and calculating a ground motion spatio-temporal field of the evaluation region through a physical simulation method based on the integrated physical model; and
S2.3, obtaining ground motion data for each of grid points in the evaluation region based on the ground motion spatio-temporal field, thereby providing ground motion parameters for evaluating the liquefaction grade of the site soil.

4. The regional seismic liquefaction spatio-temporal field construction method fusing physical simulation and machine learning according to claim 3, wherein the physical simulation method utilized in S2.2 comprises deterministic Spectral Element Method, Finite Difference Method, stochastic methods, and hybrid methods.

5. The regional seismic liquefaction spatio-temporal field construction method fusing physical simulation and machine learning according to claim 1, wherein the machine learning method in S4 comprises Linear Regression, Logistic Regression, Naive Bayes algorithm, Support Vector Machine algorithm, Random Forest algorithm, and Artificial Neural Network algorithm.

6. The regional seismic liquefaction spatio-temporal field construction method fusing physical simulation and machine learning according to claim 3, wherein in S4, a Backpropagation (BP) neural network based on the Levenberg-Marquardt algorithm is adopted for seismic liquefaction grade evaluation training to generate the seismic liquefaction grade evaluation model, wherein the seismic liquefaction grade evaluation model comprises a 3-layer neural network, namely an input layer, a hidden layer, and an output layer, the number of neurons in the input layer is 6, and the number of neurons in the hidden layer is 10, with specific steps as follows:
S4.1, forward propagation of information, configuring the 6 liquefaction grade evaluation factors from the training set as the neurons of the input layer, processing and nonlinearly transforming them through the hidden layer, and then transmitting them to the output layer;
S4.2, backward propagation of error layer by layer, after the information reaches the output layer, utilizing a loss function to calculate prediction error, then propagating error terms from the output layer back to the hidden layer, and finally to the input layer; and
S4.3, iterative updating of weights and thresholds, calculating the error in each iteration, updating weight and threshold parameters by calculating gradient of the loss function with respect to output results, repeating the forward propagation of information process described above after obtaining the updated weight and threshold parameters, until the error is less than a certain value to terminate the iteration, determining final weight and threshold results, completing model training, and generating the seismic liquefaction grade evaluation model.

7. The regional seismic liquefaction spatio-temporal field construction method fusing physical simulation and machine learning according to claim 6, wherein S5 specifically comprises: configuring the peak acceleration of the ground motion, duration of the ground motion obtained from ground motion spatio-temporal field simulation under scenario earthquake, and relative density, groundwater level, soil layer depth, and thickness of overlying non-liquefiable soil layer at each of the grid points in a evaluation region as input parameters for BP neural network, and performing liquefaction grade evaluation on each of the grid points according to a seismic liquefaction grade model, and obtaining liquefaction grade evaluation results.

8. The regional seismic liquefaction spatio-temporal field construction method fusing physical simulation and machine learning according to claim 7, wherein S6 specifically comprises:
S6.1, configuring quantified values of three-dimensional site soil liquefaction grade evaluation results as input data sources for GIS software;
S6.2, performing interpolation calculation on the quantified values of the liquefaction grade evaluation results by spatial interpolation algorithm of the GIS; and
S6.3, performing three-dimensional volume imaging of the liquefaction grade by generated three-dimensional data, and drawing a stratigraphic liquefaction grade spatial distribution map of the evaluation region.
